(19) United States
(12) Patent Application Publication
(10) Pub. No.: US 2017/0133072 A1
(43) Pub. Date: May 11, 2017

(54) Magnetic Storage Track and Magnetic Memory

(71) Applicant: Huawei Technologies Co., Ltd., Shenzhen (CN)

(72) Inventors: Yinyin Lin, Shanghai (CN); Kai Yang, Shanghai (CN); Shujie Zhang, Shenzhen (CN); Junfeng Zhao, Shenzhen (CN); Wei Yang, Hangzhou (CN); Yarong Fu, Shanghai (CN)

(21) Appl. No.: 15/402,354

(22) Filed: Jan. 10, 2017

Related U.S. Application Data
(63) Continuation of application No. PCT/CN2015/083595, filed on Jul. 8, 2015.

(30) Foreign Application Priority Data
Jul. 11, 2014 (CN) 201410330469.1

(51) Int. Cl. G11C 11/16; H01L 43/02; H01L 27/22

(52) U.S. Cl. CPC G11C 11/161; G11C 11/1673; G11C 11/1675; G11C 11/1697; H01L 27/228; H01L 43/02

(57) ABSTRACT

A magnetic storage track and a magnetic memory are provided. The magnetic storage track includes multiple stacked storage track units. A transition layer is disposed between two neighboring storage track units. The transition layer is constituted by a semiconductor material deposited on an insulating material, and includes a gating circuit and a read/write apparatus. Because the magnetic storage track includes multiple stacked storage track units, a track length of the magnetic storage track is constituted by track lengths of the multiple storage track units. Therefore, when a storage capability of the magnetic storage track needs to be improved, the track length of the magnetic storage track may be increased by adding the storage track unit.

### CROSS-REFERENCE TO RELATED APPLICATIONS

This application is a continuation of International Application No. PCT/CN2015/083595, filed on Jul. 8, 2015, which claims priority to Chinese Patent Application No. 201410330469.1, filed on Jul. 11, 2014. The disclosures of the aforementioned applications are hereby incorporated by reference in their entireties.

### TECHNICAL FIELD

Embodiments of the present disclosure relate to semiconductor technologies, and in particular, to a magnetic storage track and a magnetic memory.

### BACKGROUND

A magnetic memory is a storage device that performs information storage using a magnetization direction of a magnetic domain in a magnetic storage track. The magnetic domain refers to small magnetization regions that are generated in a spontaneous magnetization process by a magnetic material that forms the magnetic storage track to reduce magneto-static energy. The small magnetization regions contain a large quantity of atoms, and atomic magnetic moments of the atoms are neatly arranged like many small magnets. A direction in which the atomic magnetic moment is arranged is associated with a spin direction of an electron inside the atom. The atomic magnetic moment is a vector sum of orbital magnetic moments, spin magnetic moments, and nuclear magnetic moments of all electron concentrations inside the atom. Because atomic magnetic moments of neighboring magnetic domains are arranged in different directions, a magnetic domain wall is formed at a boundary between the magnetic domains. In the magnetic memory, a location of the magnetic domain wall is moved by applying a current or a magnetic field to the magnetic storage track. In this way, the direction in which the atomic magnetic moments are arranged is moved to a to-be-written magnetic domain, thereby implementing the information storage using two magnetization directions of the magnetic domains to respectively represent 0 and 1, where the magnetization directions mutually form a specific angle.

Because a storage capability of the magnetic memory is directly related to a track length of the magnetic storage track, a longer track length leads to a stronger storage capability. However, in a process of preparing the magnetic storage track, a longer track length results in a greater difficulty in a craft of manufacturing the magnetic storage track.

### SUMMARY

Embodiments of the present disclosure provide a magnetic storage track and a magnetic memory, so as to resolve a technical problem of an increased manufacturing craft difficulty caused by an increase in a track length of the magnetic storage track when a storage capability of the magnetic storage track needs to be improved.

A first aspect of the embodiments of the present disclosure provides a magnetic storage track, including multiple stacked storage track units, where a transition layer is disposed between two neighboring storage track units, each storage track unit includes a data area that is constituted by a magnetic material and configured to store data, each transition layer is constituted by a semiconductor material deposited on an insulating material, and each transition layer includes a gating circuit, where an end of the gating circuit is connected to a storage track unit stacked on the transition layer, the other end of the gating circuit is connected to a drive power supply, the gating circuit is configured to transmit a drive signal to the storage track unit stacked on the transition layer, and the drive signal is used to drive a magnetic domain in the storage track unit to move; and a read/write apparatus, connected to the storage track unit stacked on the transition layer, and configured to perform a read operation or a write operation on the magnetic domain, which is driven by the drive signal transmitted on the gating circuit, in the storage track unit stacked on the transition layer.

A second aspect of the embodiments of the present disclosure provides a magnetic memory, where the magnetic memory includes at least two magnetic storage tracks described above.

According to the magnetic storage track and the magnetic memory provided in the embodiments of the present disclosure, the magnetic storage track includes multiple stacked storage track units, a transition layer is disposed between two neighboring storage track units, and each transition layer is constituted by a semiconductor material deposited on an insulating material. Each transition layer includes a gating circuit and a read/write apparatus, where the gating circuit is configured to transmit a drive signal to a storage track unit stacked on the transition layer, and the read/write apparatus is configured to perform a read operation or a write operation on a magnetic domain, which is driven by the drive signal transmitted on the gating circuit, in the storage track unit stacked on the transition layer. Because the magnetic storage track provided in the embodiments of the present disclosure includes multiple stacked storage track units, a track length of the magnetic storage track is constituted by track lengths of the multiple storage track units. Therefore, the track length of the magnetic storage track may be increased by adding the storage track unit, which avoids increasing the track length of the storage track unit, and resolves a technical problem of an increased manufacturing craft difficulty caused by an increase in the track length of the magnetic storage track when a storage capability of the magnetic storage track needs to be improved.

### BRIEF DESCRIPTION OF DRAWINGS

To describe the technical solutions in the embodiments of the present disclosure or in the prior art more clearly, the following briefly describes the accompanying drawings required for describing the embodiments or the prior art. The accompanying drawings in the following description show some embodiments of the present disclosure.

FIG. 1 is a schematic structural diagram of a magnetic storage track in the prior art;

FIG. 2 is a schematic structural diagram of a magnetic storage track according to an embodiment of the present disclosure;

FIG. 3 is a schematic structural diagram of another magnetic storage track according to an embodiment of the present disclosure; and

FIG. 4 is a schematic structural diagram of a magnetic storage track array.

### DESCRIPTION OF EMBODIMENTS

To make the objectives, technical solutions, and advantages of the embodiments of the present disclosure more clear, the following clearly describes the technical solutions in the embodiments of the present disclosure with reference to the accompanying drawings in the embodiments of the present disclosure. The described embodiments are some but not all of the embodiments of the present disclosure.

A magnetic memory includes a drive power supply, a read/write apparatus, and a magnetic storage track. The magnetic storage track includes a magnetic domain that is configured to store data. A drive voltage provided by the drive power supply is used to apply a drive signal to the magnetic storage track, thereby driving the magnetic domain to move. The read/write apparatus may include a read apparatus and a write apparatus, where the read apparatus and the write apparatus may be disposed in parallel at a bottom of a U-shaped track, and be configured to implement a read operation or a write operation on the magnetic domain. The write apparatus may perform a write operation on a magnetic domain to write data into the magnetic domain. When the magnetic domain driven by the drive signal moves to a location of the write apparatus, a magnetization direction of the magnetic domain may be changed using the write apparatus. For example, two different magnetization directions may be used to respectively represent 0 and 1, thereby writing data into the magnetic domain. The read apparatus may perform a read operation on a magnetic domain to read data in the magnetic domain. When the magnetic domain driven by the driven signal moves to a location of the read apparatus, a magnetization direction of the magnetic domain may be recognized using the read apparatus, thereby reading the data. After a read operation or a write operation is executed on a magnetic domain, a voltage is applied to the bottom of the U-shaped track and two arms of the U-shaped track when being driven by the driven signal, and the magnetic domain is controlled to move leftward or rightward within the U-shaped track. In this way, the read/write apparatus may continue to execute a read operation or a write operation on a next magnetic domain. Using the foregoing process, data may be stored in the magnetic storage track, or data may be read from the magnetic storage track.

In the embodiments of the present disclosure, the read apparatus and the write apparatus are collectively referred to as the read/write apparatus. It may be understood that the magnetic storage track may not be limited to a U shape, and may further be an I shape, an L shape, or the like. When the magnetic storage track is another shape except a U shape, the read/write apparatus may be disposed in another part of the magnetic storage track, provided that the read/write apparatus can perform a read operation or a write operation on a magnetic domain in the magnetic storage track.

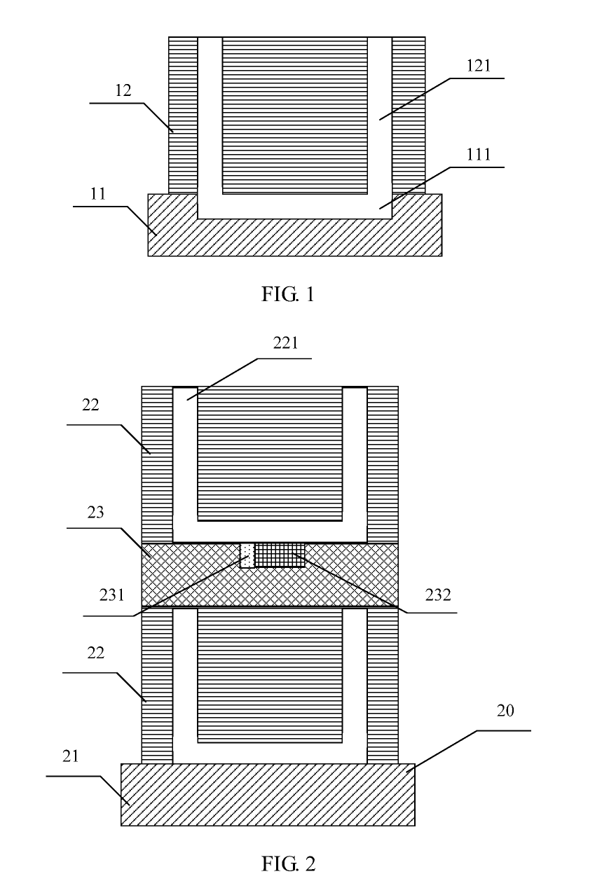

FIG. 1 is a schematic structural diagram of a magnetic storage track in the prior art. The magnetic storage track includes a substrate 11 and an etching zone 12 that are interconnected, where a U-shaped track may be disposed inside the magnetic storage track and serve as a data area, the U-shaped track is made of a magnetic material, two paralleled arms 121 (a left arm and a right arm) of the U-shaped track are located in the etching zone, and a bottom 111 of the track is located in the substrate. When the U-shaped track is prepared, on a surface connected to the etching zone, etching is first performed on the substrate to obtain the bottom of the U-shaped track; then, etching is performed on the etching zone on a surface of the etching zone to obtain grooves whose bottom is connected to the substrate, thereby obtaining the two left and right arms of the U-shaped track; finally, the U-shaped track is filled with a magnetic material to obtain the magnetic storage track shown in FIG. 1.

A storage capability of the magnetic memory is directly related to a track length of the magnetic storage track. In an example in which the data area is the U-shaped track, longer lengths of the two arms 121 of the U-shaped track lead to more contained magnetic domains and a stronger storage capability of the magnetic storage track. However, in a process of preparing a U-shaped track in the prior art, if a relatively long track length needs to be obtained, a thickness of an etching zone needs to be increased, and then a relatively deep groove needs to be etched in the etching zone, where the groove is configured to deposit a magnetic material to obtain a data area. When a depth of the etched groove increases to several hundred nanometers, a sidewall of the groove is generally sloping, instead of presenting an expected right angle with a bottom of the groove, and a surface is uneven and unsmooth, which greatly affects stability of the magnetic storage track.

FIG. 2 is a schematic structural diagram of a magnetic storage track 20 according to an embodiment of the present disclosure. In a possible implementation manner, the magnetic storage track 20 in FIG. 2 includes a U-shaped storage track that serves as a data area. A person skilled in the art may learn that the data area may further be a storage track of another shape, which is not limited in this embodiment. As shown in FIG. 2, the magnetic storage track 20 in this embodiment includes multiple stacked storage track units 22, where a transition layer 23 is disposed between two neighboring storage track units 22, and each storage track unit 22 includes a data area 221 that is constituted by a magnetic material and configured to store data.

Each transition layer 23 is constituted by a semiconductor material deposited on an insulating material. In a process of preparing the magnetic storage track 20, the insulating material may be deposited on a substrate 21; then, etching is performed on a surface of the deposited insulating material to obtain a groove, and a magnetic material is deposited inside the groove to serve as a data area and finally form the storage track unit 22; subsequently, a semiconductor material is deposited on the formed storage track unit 22, and steps of etching and preparing a gating circuit 231 and a read/write apparatus 232 are successively performed on a surface of the deposited semiconductor material to finally form the transition layer 23. Steps of alternately forming the storage track unit 22 and the transition layer 23 are repeatedly performed to finally obtain the magnetic storage track 20. The semiconductor material that forms the transition layer 23 is different from a semiconductor material that forms the substrate. For example, the semiconductor material that forms the substrate is monocrystalline silicon, and the material that forms the transition layer 23 is polycrystalline silicon or a polycrystalline silicon compound.

Each transition layer 23 includes the gating circuit 231 and the read/write apparatus 232. An end of the gating circuit 231 is connected to a storage track unit 22 stacked on the transition layer, the other end of the gating circuit 231 is connected to a drive power supply, the gating circuit 231 is configured to transmit a drive signal to the storage track unit 22 stacked on the transition layer 23, and the drive signal is used to drive a magnetic domain in the storage track unit 22 to move.

The read/write apparatus 232 is connected to the storage track unit 22 stacked on the transition layer 23, and is configured to perform a read operation or a write operation on the magnetic domain, which is driven by the drive signal transmitted on the gating circuit 231, in the storage track unit 22 stacked on the transition layer 23. That is, the read/write apparatus 232 is configured to read data from the magnetic domain or write data into the magnetic domain.

The magnetic storage track provided in this embodiment includes multiple stacked storage track units, a transition layer is disposed between two neighboring storage track units. The transition layer is constituted by a semiconductor material deposited on an insulating material. The transition layer includes a gating circuit that is configured to transmit a drive signal to the storage track unit stacked on the transition layer, and a read/write apparatus that is configured to perform a read operation or a write operation on a magnetic domain, which is driven by the drive signal transmitted on the gating circuit, in the storage track unit stacked on the transition layer. Because the magnetic storage track includes multiple stacked storage track units, a track length of the magnetic storage track is constituted by track lengths of the multiple storage track units. Therefore, the track length of the magnetic storage track may be increased by adding the storage track unit, which avoids increasing the track length of the storage track unit, and resolves a technical problem of an increased craft difficulty caused by an increase in the track length of the magnetic storage track when a storage capability of the magnetic storage track needs to be improved.

In addition, a manner in which multiple stacked storage track units are used and a transition layer is disposed between two neighboring storage track units is used in this embodiment of the present disclosure. This reduces a depth of a groove that is etched in the storage track unit and configured to deposit a magnetic material to obtain a data area, which avoids occurrence of a situation in which a sidewall of the groove is sloping and has an uneven and unsmooth surface. Moreover, the situation in which the sidewall of the groove is sloping and has an uneven and unsmooth surface may disturb atoms inside the magnetic domain, change an atomic magnetic moment, and further change data stored in the magnetic domain. This embodiment of the present disclosure can effectively avoid the situation in which the sidewall of the groove is sloping and has an uneven and unsmooth surface, thereby improving stability of the magnetic storage track.

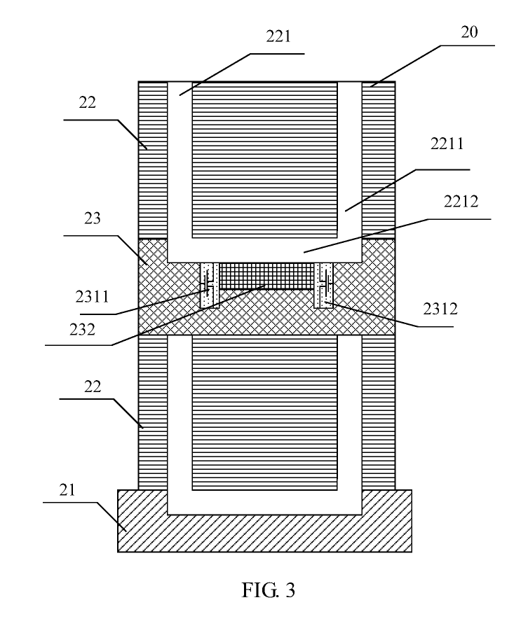

FIG. 3 is a schematic structural diagram of another magnetic storage track 20 according to an embodiment of the present disclosure. As shown in FIG. 3, based on the foregoing embodiment, the storage track unit 22 in this embodiment includes a U-shaped storage track that serves as the data area 221.

The U-shaped storage track includes two arms 2211 of the U-shaped track and a bottom 2212 of the U-shaped track.

The two arms 2211 of the U-shaped track are respectively connected to two ends of the bottom 2212 of the U-shaped track. The bottom 2212 of the U-shaped track is built in the transition layer 23. The storage track unit 22 formed on the transition layer 23 is obtained by alternately depositing two different materials, for example, alternately depositing Si and SiO₂, or alternately depositing SiO₂ and Si₃N₄. The two arms 2211 of the U-shaped track inside the storage track unit 22 are obtained by depositing a magnetic material inside a groove after the groove is etched in the storage track unit 22. The bottom 2212 that is of the U-shaped track and built in the transition layer 23 is obtained by depositing, after another groove is etched on a surface of the transition layer 23, a magnetic material in the groove.

The gating circuit 231 and the read/write apparatus 232 are disposed beneath the U-shaped track.

The gating circuit 231 and the read/write apparatus 232 are separately connected to the bottom 2212 of the U-shaped track.

The gating circuit 231 includes a metal oxide semiconductor (MOS) field-effect transistor, which may be referred to as a MOS transistor in this embodiment of the present disclosure. A first end of the MOS transistor is configured to input a control signal, where the control signal is used to control the MOS transistor to be in a connected state or a disconnected state. A second end of the MOS transistor is connected to the storage track unit 22 stacked on the transition layer. A third end of the MOS transistor is connected to the drive power supply, and is configured to transmit, when the MOS transistor is in the connected state, the drive signal to the storage track unit stacked on the transition layer.

In a case, the first end of the MOS transistor may be a gate electrode of the MOS transistor, the second end of the MOS transistor may be a source electrode of the MOS transistor, and the third end of the MOS transistor may be a drain electrode of the MOS transistor. In another case, the first end of the MOS transistor may be a gate electrode of the MOS transistor, the second end of the MOS transistor may be a drain electrode of the MOS transistor, and the third end of the MOS transistor may be a source electrode of the MOS transistor. A voltage may be applied to the U-shaped track using the third end of the MOS transistor, so that the magnetic domain in the U-shaped track moves along the U-shaped track according to a difference between the voltage applied using the third end of the MOS transistor and a voltage applied to the two arms 2211 of the U-shaped track. It may be understood that the voltage is merely one type of the drive signal. In practical application, a drive signal of another form, such as a current or a pulse, may further be applied to the U-shaped track using the third end of the MOS transistor, provided that the magnetic domain can be driven to move. In this embodiment of the present disclosure, the MOS transistor may be a thin film transistor (TFT).

It should be noted that, that the magnetic domain moves along the U-shaped track does not mean that a physical position of the magnetic domain moves along the U-shaped track, but means that a magnetization direction of the magnetic domain transfers along a direction of the U-shaped track.

Further, the gating circuit 231 at each transition layer 23 includes two MOS transistors, that is, a first MOS transistor 2311 and a second MOS transistor 2312. The first MOS transistor 2311 and the second MOS transistor 2312 are respectively disposed on two sides of the read/write apparatus 232, where the first MOS transistor 2311 is configured to transmit a drive signal to a first-side track of the U-shaped storage track, and the second MOS transistor 2312 is configured to transmit a drive signal to a second-side track of the U-shaped storage track.

For the two MOS transistors included in the gating circuit 231 at each transition layer 23, the first MOS transistor 2311 on a first side is configured to transmit the drive signal to one arm, namely, the first-side track of the U-shaped storage track, and the second MOS transistor 2312 on a second side is configured to transmit the drive signal to the other arm, namely, the second-side track of the U-shaped storage track.

Further, the magnetic storage track 20 includes at least two transition layers, and third ends of MOS transistors that are located on a same side and at the at least two transition layers are jointly connected to the drive power supply in a magnetic memory. In this way, different storage track units in the magnetic storage track 20 are corresponding to tracks on a same side, and magnetic domains in the tracks on the same side are driven by a same drive signal to simultaneously move. Every time the drive signal drives the magnetic domains, read/write apparatuses corresponding to the different storage track units may synchronously perform operations on the storage track units corresponding to the read/write apparatuses. This implements paralleled data input or output in the tracks on the same side that are corresponding to the different storage track units in the magnetic storage track 20.

For each MOS transistor included in the gating circuit 231 in the transition layer 23, the first end of the MOS transistor receives the control signal; the third end of the MOS transistor is connected to the drive power supply in the magnetic memory to receive the drive signal. The drive signal is used to drive the magnetic domain in the storage track unit to move, and the control signal is used to control the MOS transistor to be in the connected state or the disconnected state. In an operating process of the magnetic storage track 20, an operation may be performed on one storage track unit 22 in the multiple storage track units 22 using the control signal and the drive signal. For example, when the magnetic storage track 20 includes three storage track units 22, an operation may be performed on a middle storage track unit 22, a control signal different from that sent to another MOS transistor may be sent to a MOS transistor corresponding to the middle storage track unit 22, so that the MOS transistor corresponding to the middle storage track unit 22 is in the connected state, while MOS transistors corresponding to remaining storage track units 22 are in the disconnected state. Then, a drive signal is sent to the MOS transistor corresponding to the middle storage track unit 22, so as to control a magnetic domain in the middle storage track unit 22 to move.

According to this embodiment of the present disclosure, because a magnetic storage track includes multiple stacked storage track units, a track length of the magnetic storage track is constituted by track lengths of the multiple storage track units. Therefore, the track length of the magnetic storage track may be increased by adding the storage track unit, which avoids increasing the track length of the storage track unit, and resolves a technical problem of an increased craft difficulty caused by an increase in the track length of the magnetic storage track when a storage capability of the magnetic storage track needs to be improved. In addition, third ends of MOS transistors that are located on a same side and at at least two transition layers are jointly connected to a drive power supply in a magnetic memory. In this way, different storage track units in the magnetic storage track are corresponding to tracks on a same side, and magnetic domains in the tracks on the same side are driven by a same drive signal to simultaneously move. Every time the drive signal drives the magnetic domains to move, read/write apparatuses corresponding to the different storage track units may synchronously perform operations on the storage track units corresponding to the read/write apparatuses. This implements paralleled data input and output in the tracks on the same side of the U-shaped track, thereby increasing read/write bandwidth.

Another embodiment of the present disclosure further provides a magnetic memory that includes multiple magnetic storage tracks 20 described in the foregoing embodiments. Substrates 21 of the multiple magnetic storage tracks 20 described in the foregoing embodiments are interconnected. In addition, the magnetic memory may further include a drive power supply.

The drive power supply is connected to the multiple magnetic storage tracks, and the multiple magnetic storage tracks are arranged in an array form in rows and columns.

In a case, if the magnetic storage track is a U-shaped magnetic storage track, two left and right arms of the U-shaped magnetic storage track respectively form tracks on two sides. First-side tracks of U-shaped magnetic storage tracks in a same row share a same control signal, and second-side tracks of U-shaped magnetic storage tracks in a same row share a same control signal. First-side tracks of U-shaped magnetic storage tracks in a same column are connected to a same drive power supply, and second-side tracks of U-shaped magnetic storage tracks in a same column are connected to a same drive power supply.

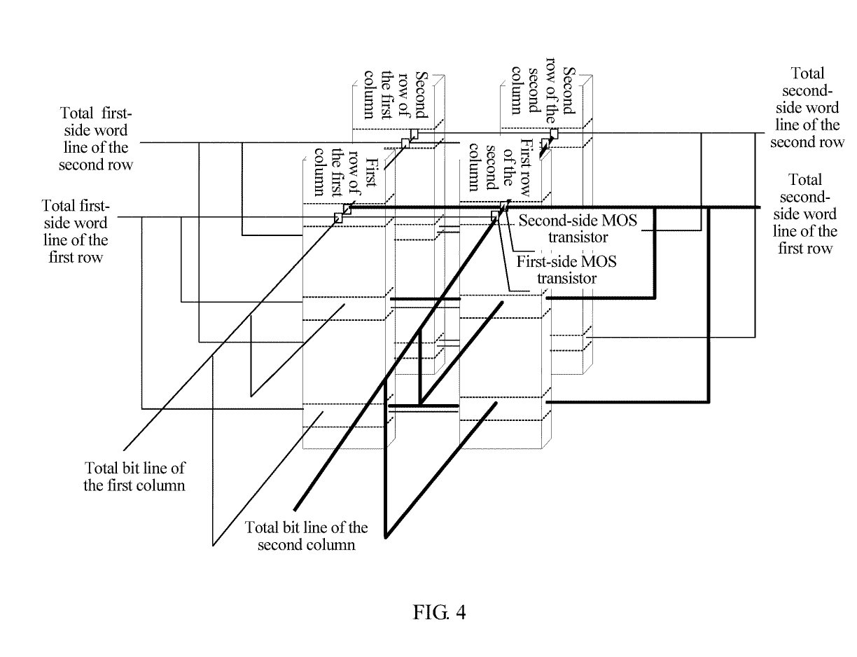

If there are at least two magnetic storage tracks, and the magnetic storage tracks are arranged into an array having N rows and M columns, word lines that are at a corresponding transition layer, of magnetic storage tracks in a same row, and used for receiving a control signal are interconnected to form connection lines, and then the connection lines of various transition layers are interconnected to obtain a total word line. FIG. 4 is a schematic structural diagram of a magnetic storage track array. As shown in FIG. 4, first-side word lines at a corresponding transition layer and of magnetic storage tracks in a same row are interconnected, and second-side word lines at a corresponding transition layer and of magnetic storage tracks in a same row are interconnected. When each transition layer includes two MOS transistors, which are respectively denoted as a first-side MOS transistor and a second-side MOS transistor, the first-side word lines are a word line connected to the first-side MOS transistor. Likewise, the second-side word lines are a word line connected to the second-side MOS transistor. Connection lines obtained by interconnecting first-side word lines at each transition layer are interconnected to obtain a total first-side word line, and connection lines obtained by interconnecting second-side word lines at each transition layer are interconnected to obtain a total second-side word line. With respect to a bit line for receiving a drive signal, bit lines that are at each transition layer and are connected to different MOS transistors are interconnected first. In a same column, bit lines at a corresponding transition layer and of magnetic storage tracks in the same column are interconnected, and then connection lines obtained by interconnecting the bit lines of various transition layers are interconnected to obtain a total bit line of this column.

In an operating process of the magnetic memory, a control signal and a drive signal may be used to perform gating and an operation on only a track on one side of one U-shaped magnetic storage track in the multiple U-shaped magnetic storage tracks. For example, when a magnetic memory includes U-shaped magnetic storage tracks in two rows of two columns, if gating and an operation need to be performed on a second-side track of a U-shaped magnetic storage track in the first row of the second column, a total bit line of the second column may be used to receive a control signal that instructs to control a MOS transistor to be in a connected state, a total bit line of the first column may be used to receive a control signal that instructs to control a MOS transistor to be in a disconnected state, and a total second-side word line of the first row may be used to receive a drive signal that instructs to drive a magnetic domain to move. According to the drive signal, a second-side MOS transistor controls a magnetic domain in the second-side track to move, and after a magnetic domain movement is completed, instructs a read/write apparatus to perform a read operation or a write operation. In the foregoing manner, the gating and the operation on the second-side track of the U-shaped magnetic storage track in the first row of the second column are implemented, so as to read data from the magnetic domain in the second-side track of the U-shaped magnetic storage track in the first row of the second column or to store data into the magnetic domain in the second-side track of the U-shaped magnetic storage track in the first row of the second column.

It should be noted that in this embodiment of the present disclosure, for ease of description, magnetic storage tracks that share a drive signal are referred to as same-column magnetic storage tracks, and magnetic storage track that share a control signal are referred to as same-row magnetic storage tracks. Both a row and a column described in this embodiment of the present disclosure refer to a row and a column in logic. In this manner, same-column magnetic storage tracks are not limited to being in a same column in terms of a physical position, provided that the magnetic storage tracks logically share a bit line to obtain a drive signal. In addition, same-row magnetic storage tracks are not limited to being in a same row in terms of a physical position.

According to this embodiment of the present disclosure, because a magnetic storage track includes multiple stacked storage track units, a track length of the magnetic storage track is constituted by track lengths of the multiple storage track units. Therefore, the track length of the magnetic storage track may be increased by adding the storage track unit, which avoids increasing the track length of the storage track unit, and resolves a technical problem of an increased craft difficulty caused by an increase in the track length of the magnetic storage track when a storage capability of the magnetic storage track needs to be improved. In addition, according to a layout method and a connection method of the magnetic storage track in this embodiment, first-side tracks of U-shaped magnetic storage tracks in a same row share a same control signal, second-side tracks of U-shaped magnetic storage tracks in a same row share a same control signal, first-side tracks of U-shaped magnetic storage tracks in a same column are connected to a same drive power supply, and second-side tracks of U-shaped magnetic storage tracks in a same column are connected to a same drive power supply. This implements that gating and an operation are performed on only a track on one side of one U-shaped magnetic storage track in the multiple U-shaped magnetic storage tracks, thereby improving flexibility.

Finally, it should be noted that the foregoing embodiments are merely intended for describing the technical solutions of the present disclosure, but not for limiting the present disclosure. The embodiments provided in the present application are merely exemplary. A person skilled in the art may clearly understand that, for the purpose of convenient and brief description, in the foregoing embodiments, the descriptions of the embodiments have their respective focuses. For a part that is not described in detail in an embodiment, reference may be made to related descriptions in other embodiments. The characteristics disclosed in the embodiments of the present disclosure, in the claims, and in the accompanying drawings may independently exist or may exist in a combination.

What is claimed is:

1. A magnetic storage track, comprising:
multiple stacked storage track units; and
a transition layer disposed between two neighboring storage track units,
wherein each storage track unit comprises a data area that is constituted by a magnetic material and configured to store data,
wherein each transition layer is constituted by a semiconductor material deposited on an insulating material, and
wherein each transition layer comprises:
a gating circuit, wherein a first end of the gating circuit is connected to a storage track unit stacked on the transition layer, wherein a second end of the gating circuit is connected to a drive power supply, wherein the gating circuit is configured to transmit a drive signal to the storage track unit stacked on the transition layer, and wherein the drive signal is used to drive a magnetic domain in the storage track unit to move; and
a read/write apparatus connected to the storage track unit stacked on the transition layer and configured to perform a read operation or a write operation on the magnetic domain, which is driven by the drive signal transmitted on the gating circuit, in the storage track unit stacked on the transition layer.

2. The magnetic storage track according to claim 1, wherein the gating circuit comprises a metal oxide semiconductor (MOS) transistor, wherein the MOS transistor comprises:
a first end of the MOS transistor configured to input a control signal, wherein the control signal is used to control the MOS transistor to be in a connected state or a disconnected state;
a second end of the MOS transistor connected to the storage track unit stacked on the transition layer; and
a third end of the MOS transistor connected to the drive power supply and configured to transmit the drive signal to the storage track unit stacked on the transition layer when the MOS transistor is in the connected state.

3. The magnetic storage track according to claim 2, wherein the magnetic storage track comprises at least two transition layers, and wherein third ends of MOS transistors that are located in a same column at the at least two transition layers are jointly connected to the drive power supply.

4. The magnetic storage track according to claim 2, wherein the storage track unit stacked on the transition layer comprises a U-shaped storage track, and wherein the gating circuit and the read/write apparatus are disposed at a bottom of the U-shaped storage track.

5. The magnetic storage track according to claim 4, wherein the gating circuit comprises:
a first MOS transistor configured to transmit a first drive signal to a first-side track of the U-shaped storage track; and
a second MOS transistor configured to transmit a second drive signal to a second-side track of the U-shaped storage track, and wherein the first MOS transistor and the second MOS transistor are respectively disposed on two sides of the read/write apparatus.

6. The magnetic storage track according to claim 2, wherein the MOS transistor comprises a thin film transistor (TFT).

7. The magnetic storage track according to claim 1, wherein the semiconductor material deposited on the insulating material comprises polycrystalline silicon or a polycrystalline silicon compound.

8. A magnetic memory, comprising:
at least two magnetic storage tracks, wherein each magnetic storage track comprises multiple stacked storage track units; and
a transition layer is disposed between two neighboring storage track units,
wherein each storage track unit comprises a data area that is constituted by a magnetic material and configured to store data,
wherein each transition layer is constituted by a semiconductor material deposited on an insulating material, and
wherein each transition layer comprises:
a gating circuit, wherein a first end of the gating circuit is connected to a storage track unit stacked on the transition layer, wherein a second end of the gating circuit is connected to a drive power supply, wherein the gating circuit is configured to transmit a drive signal to the storage track unit stacked on the transition layer, and wherein the drive signal is used to drive a magnetic domain in the storage track unit to move; and
a read/write apparatus connected to the storage track unit stacked on the transition layer and configured to perform a read operation or a write operation on the magnetic domain, which is driven by the drive signal transmitted on the gating circuit, in the storage track unit stacked on the transition layer.

9. The magnetic memory according to claim 8, wherein the magnetic storage track comprises a U-shaped magnetic storage track, wherein first-side tracks of U-shaped magnetic storage tracks in a same row share a same control signal, wherein second-side tracks of U-shaped magnetic storage tracks in a same row share a same control signal, wherein first-side tracks of U-shaped magnetic storage tracks in a same column are connected to a same drive power supply, and wherein second-side tracks of U-shaped magnetic storage tracks in a same column are connected to a same drive power supply.

10. The magnetic memory according to claim 8, wherein the gating circuit comprises a metal oxide semiconductor (MOS) transistor, wherein the MOS transistor comprises:
a first end of the MOS transistor configured to input a control signal, wherein the control signal is used to control the MOS transistor to be in a connected state or a disconnected state;
a second end of the MOS transistor connected to the storage track unit stacked on the transition layer; and
a third end of the MOS transistor connected to the drive power supply and configured to transmit the drive signal to the storage track unit stacked on the transition layer when the MOS transistor is in the connected state.

11. The magnetic memory according to claim 10, wherein a magnetic storage track of the at least two magnetic storage tracks comprises at least two transition layers, and wherein third ends of MOS transistors that are located in a same column at the at least two transition layers are jointly connected to the drive power supply.

12. The magnetic memory according to claim 10, wherein the storage track unit stacked on the transition layer comprises a U-shaped storage track, and wherein the gating circuit and the read/write apparatus are disposed at a bottom of the U-shaped storage track.

13. The magnetic memory according to claim 12, wherein the gating circuit comprises:
a first MOS transistor configured to transmit a first drive signal to a first-side track of the U-shaped storage track; and
a second MOS transistor configured to transmit a second drive signal to a second-side track of the U-shaped storage track, wherein the first MOS transistor and the second MOS transistor are respectively disposed on two sides of the read/write apparatus.

14. The magnetic memory according to claim 10, wherein the MOS transistor comprises a thin film transistor (TFT).

15. The magnetic memory according to claim 8, wherein the semiconductor material deposited on the insulating material comprises polycrystalline silicon or a polycrystalline silicon compound.
